(19) United States
(12) Patent Application Publication
(10) Pub. No.: US 2017/0330986 A1
(43) Pub. Date: Nov. 16, 2017

(54) INTERMETALLIC BONDED MULTI-JUNCTION STRUCTURES

(71) Applicant: North Carolina State University, Raleigh, NC (US)

(72) Inventor: Salah Bedair, Raleigh, NC (US)

(21) Appl. No.: 15/593,414

(22) Filed: May 12, 2017

Related U.S. Application Data
(60) Provisional application No. 62/335,167, filed on May 12, 2016.

(51) Int. Cl. H01L 31/056; H01L 31/0216; H01L 31/0236; H01L 31/0725

(52) U.S. Cl. CPC H01L 31/056; H01L 31/0725; H01L 31/02168; H01L 31/02363

(57) ABSTRACT

Multiple semiconductor p-n junctions may be built into a single structure to expand the optical capabilities of a device. For example, multi-junction solar cells have improved efficiencies and thus may be desirable for a variety of reasons. Typically, tunnel junctions have been used to connect the plurality of junctions in a two-terminal, layered structure, wherein the junctions are in series electrically and optically. This approach has a variety of drawbacks that lead to higher cost and complexity. The present disclosure embraces an intermetallic bonded multi-junction solar cell that eliminates the problems associated with tunnel junctions and offers additional improvements, such as, photon recycling, light trapping, and simplicity. The present disclosure can also be used as a substitute for wafer bonding with potential advantages for high solar concentration applications. It can also be used in bonding LED structures to achieve white light and dual color LEDs

### CROSS-REFERENCE TO RELATED APPLICATION

This application claims the benefit of U.S. Provisional Patent Application No. 62/335,167 filed on May 12, 2016, which is hereby incorporated by reference in its entirety.

### FIELD OF THE INVENTION

The present disclosure relates to semiconductor devices and more specifically, to multi-junction solar cells in which multiple junctions are connected by intermetallic bonding.

### BACKGROUND

Solar energy is a fast growing segment of the energy industry. Today, 20GW of solar energy (enough to power 4.6 million households) is generated in the US alone. Solar cells are used to convert solar energy into electrical energy. The conversion efficiency in typical (single junction) solar cells is low (e.g., 15-20%). Multi-junction (MJ) solar cells, on the other hand, are an attractive technology for solar energy generation due to their high efficiency (e.g., >20%). MJ solar cells are solar cells that have multiple semiconductor p-n junctions (i.e., junctions). Each junction may be constructed using different semiconductor materials to provide sensitivity to different wavelengths. In this way, a MJ solar cell is capable of absorbing a broad range of wavelengths, thereby improving efficiency. The complexity and manufacturing cost of MJ structures, however, is high, which results in a price-to-performance ratio that limits widespread usage.

An MJ solar cell requires a careful choice of materials because the multiple junctions (i.e., cells) must be attached. The materials of the junctions are typically chosen to have matching crystalline characteristics (e.g., lattice matching), electrical characteristics (e.g., current matching), thermal characteristics (e.g., thermal junction temperature, thermal expansion coefficient, thermal matching), and/or optical performance characteristics (e.g., absorption/emission wavelength which is determined by the band gap). As a result, the choices are often limited.

All high efficiency multi-junction solar cells are connected using a connecting junction, such as a tunnel junction (TJ). Without the tunnel junction, the p/n (i.e., interface between a p-type material and an n-type material) of a first cell connected directly with the p/n of a second cell (e.g., in series—p/n/p/n) creates a reverse-biased junction at the interface between the two cells. The reverse-biased junction prevents current flow in the MJ solar cell. A tunnel junction inserted between the cells prevents the reverse-biased junction and facilitates the MJ solar cell's operation. An exemplary MJ solar cell with a tunnel junction is shown in FIG. 1. As shown, the stack 50 consists of a tunnel junction 30 inserted between the top cell 10 and the bottom cell 20.

The tunnel junction (TJ) 30 is a heavily doped junction (i.e., p+/n+) that, when positioned between the top cell 10 and the bottom cell 20, acts as a conductor. The n-layer of the bottom cell 5 is connected to the n+ layer of a TJ 35, whereas the p-layer of the top cell 15 is connected to the p+ of the TJ 25. In this configuration, both TJ layers 25, 35 act as ohmic contacts (i.e., the TJ p+/n+ is ohmic).

Tunnel junctions are an essential for multi-junction (MJ) photovoltaic cells. The TJ behaves like a quasi-ohmic contact at low biases, thereby allowing adjacent cells (i.e., sub-cells) to be connected without the formation of a parasitic diode. A TJ may be judged by its ability to satisfy a few criteria. First, to avoid absorption, the TJ should be composed of materials that have a band gap higher than the cells (e.g., top cell, bottom cell). Second, to resist thermal annealing (e.g., during growth) the dopant species of the TJ should have minimal thermal diffusion. Third, the TJ should be capable of supporting the highest operating current densities of the MJ stack 50 with a small voltage drop across the TJ.

In many cases it is difficult, or impossible, to satisfy all criteria. One reason for this is TJs using several material systems (e.g., GaN based structure) are difficult to achieve. Another reason for this is high doping levels (e.g., 10¹⁹/cm³) of TJs are very difficult to achieve. Still another reason for this is dopants in TJs must have a very low diffusion coefficient when subjected to the high temperatures experienced during epitaxial growth of other cells. Yet another reason for this is TJs must be fabricated from material systems that are lattice matched (e.g., the substrate, bottom cell, and top cell are matched). Without lattice matching, the quality of the top cell grown on the TJ will be compromised and high efficiencies cannot be achieved. These TJ difficulties increase the cost and complexity of MJ solar cell fabrication.

One known approach for fabricating MJ solar cells uses wafer bonding. Wafer bonding connects layers of the same doping nature (e.g., an n-layer to another n-layer). Wafer bonding does not eliminate the need of a TJ, however, since the TJ allows for the connection of an n-layer to a p-layer without adverse effects. Examples of wafer bonding include III-V cells on silicon (Si), Gallium Nitride (GaN) on Si, and Si on Germanium (Ge).

Wafer bonded MJ solar cells (including a TJ) offer high performance. For example, record performance MJ solar cell structures having a higher than 45% efficiency have been created by bonding GaAs/TJ/InGaP subcells lattice matched to GaAs, to InGaAsP/TJ/InGaAs sub cells, lattice matched to InP substrate. Wafer bonding is limited, however, for a variety of reasons.

First, the wafer bonding process is not universal and not applicable to all material combinations, such as exotic materials (e.g., II-VI, CuInGaSe, perovskite, organic, etc.) combined with conventional materials (e.g., Si, Ge, III-V, etc.).

Second, the wafer boding process may suffer from the presence of air bubbles that compromise the conversion efficiencies.

Third, all MJ solar cell structures fabricated using wafer bonding suffer from a drop in fill-factor (FF) when used with solar concentrations higher than a few 100×. This loss of quality is due to the wafer-bonded interfaces.

Fourth, a structure having an air gap between the top and bottom cell is good for photon recycling; however, these structures cannot be created via wafer bonding.

Fifth, wafer bonding can be costly, complex and may require costly equipment, since it requires synthesis of connecting junctions and deposition of different-material layers on the same substrate.

A need, therefore, exists for a MJ solar cell structure that mitigates the limitations of both TJ and wafer bonding as described above, and that allows for easy/cost-efficient fabrication by allowing off the shelf solar cells (e.g., Si, CdTe, CuInGaSe) to be integrated into a MJ structure (i.e., stack) without the need for a TJ layer and without the need of the TJ layer's required epitaxial growth process.

### SUMMARY

Accordingly, in one aspect, the present disclosure is directed to an intermetallic bonded multi-junction (MJ) solar cell. The intermetallic bonded (MJ) solar cell includes two junctions (i.e., cells) that are connected by an intermetallic bond formed through heat and/or pressure. Each cell includes contacts connected by a contact grid. A thin film of indium is applied the surface of the contacts and (in some cases) the contact grid to form an indium pad. The cells are joined by an intermetallic bond between the indium pads of each cell.

The structure results in an air gap between the two junctions that allows for light trapping and photon recycling. The intermetallic bond allows for the two junctions, which differ in their crystalline, electrical, thermal, or optical characteristics, to be bonded without the need for special processing to match any or all of these characteristics. As a result, junctions of different materials may be easily integrated into a two-terminal device that can withstand highly concentrated light. In addition, commercial off the shelf (COTS) solar cells may be integrated into MJ solar cells using this approach.

In exemplary embodiments, either or both of the junctions are single p-n junctions or multiple p-n junctions.

In another exemplary embodiment, the contacts on either or both of the two junctions is an ohmic contact grid. In some embodiments, the contact grid is covered with indium metal and bonding can take place between indium pads (i.e., bumps) and the contact grid.

In another exemplary embodiment, a surface on either or both of the junctions has a surface texture for coupling light.

In another exemplary embodiment, a surface on either or both of the junctions has an optical antireflection coating.

In another aspect, the present disclosure is directed to an intermetallic multi-junction (MJ) solar cell that utilizes flip chip technology for the intermetallic bond. The intermetallic bonded (MJ) solar cell includes two junctions (i.e., cells) that are connected by an intermetallic bond formed through heat and pressure. A first cell (e.g., lower junction or junctions) includes contacts connected by a contact grid. A thin film of indium is applied the surface of the contacts and the contact grid to form an indium pad. A second cell (e.g., upper junction or junctions) includes indium bumps distributed over a surface of the second cell. The cells are joined by an intermetallic bond between the indium pad and the indium bumps.

In an exemplary embodiment, the indium bumps are connected to the second cell via contacts situated between each indium bump and the second junction.

As with the previous embodiment, an air gap is formed between the two cells that allows for light trapping and photon recycling. In addition, the intermetallic bond allows the two cells to differ in their crystalline, electrical, thermal, or optical characteristics without the need for special processing to match any or all of these characteristics. As a result, cells of different materials may be easily integrated into a two-terminal device that can withstand concentrated light.

The foregoing illustrative summary, as well as other exemplary objectives and/or advantages of the disclosure, and the manner in which the same are accomplished, are further explained within the following detailed description and its accompanying drawings.

Other systems, methods, features, and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

FIG. 1 is a side view of a multi-junction solar cell having a tunnel junction according to the prior art.

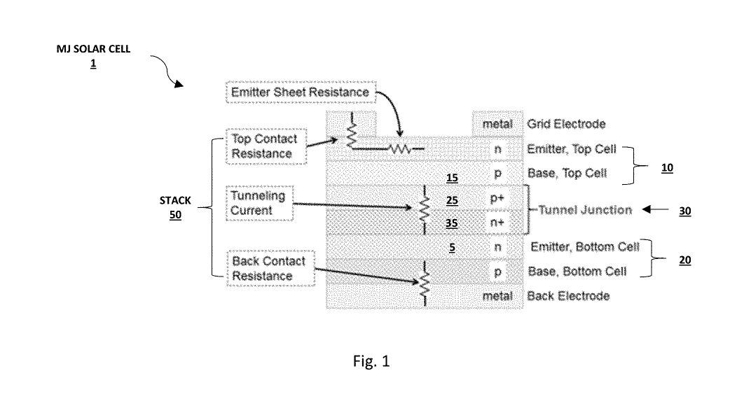

FIG. 2 graphically illustrates perspective, exploded views of two possible embodiments of the intermetallic bonded MJ solar cell, wherein one the possible embodiment has crossed pads (left), while the other possible embodiment has aligned pads (right).

FIG. 3 is a perspective, exploded view of an intermetallic bonded MJ solar cell according an exemplary embodiment of the present disclosure.

FIG. 4 is a side view of the MJ solar cell shown in FIG. 1 after bonding.

FIG. 5 is a perspective, exploded view of an intermetallic bonded MJ solar cell according to a second exemplary embodiment of the present disclosure.

FIGS. 6A-6C graphically illustrate various views of components in the intermetallic bonded MJ solar cell of FIG. 4, wherein FIG. 6A is a top view of the bottom cell, FIG. 6B is a side view of the top cell, and FIG. 6C is a perspective view of the top cell.

FIGS. 7A-7C graphically illustrate various views of components in the intermetallic bonded MJ solar cell of FIG. 4, wherein FIG. 7A is a top view of the bottom cell, FIG. 7B is a side view of the top cell, and FIG. 7C is a perspective view of the top cell.

FIG. 8 illustrates current-voltage (I-V) plots of an exemplary intermetallic bonded structure.

FIG. 9 illustrates I-V characteristics of a solar cell before and after intermetallic bonding according to an exemplary embodiment of the present disclosure.

FIG. 10 illustrates the I-V characteristics of a multi-junction intermetallic bonded GaAs/Si solar cell according to an embodiment of the present disclosure.

FIG. 11 illustrates the I-V characteristics of an intermetallic bonded p-type GaN and n-type GaN structure used as a substitute for a tunnel junction according to an embodiment of the present disclosure.

The components in the drawings are not necessarily to scale relative to each other. Like callouts or reference numerals designate corresponding parts throughout the several views.

### DETAILED DESCRIPTION

The systems and methods disclosed herein are directed to multi-junction semiconductor devices and more specifically, to an intermetallic bonded multi-junction solar cell (MJ solar cell). The disclosure includes details regarding exemplary MJ solar cell structures and methods for the fabrication thereof.

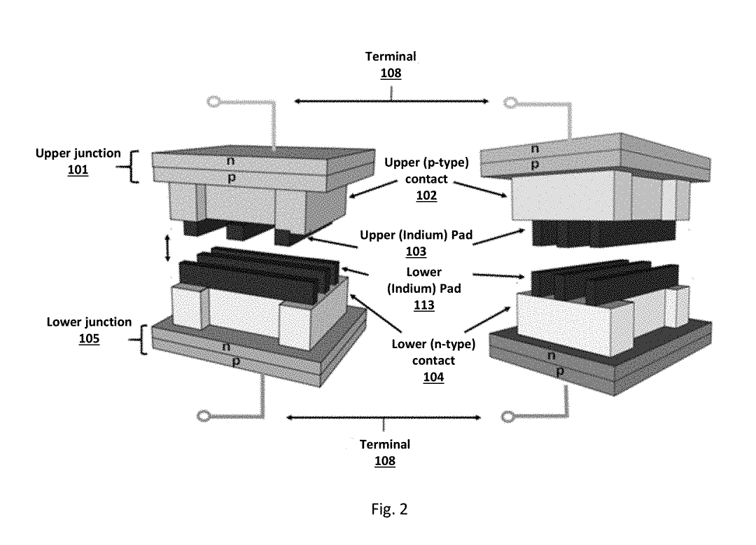

Exploded perspective views of two possible embodiments of an MJ solar cell are shown in FIG. 2. In a first embodiment (left), the top indium pads 103 and bottom indium pads 113 are configured to cross, while in a second embodiment (right) the top/bottom indium pads 103,113 are configured to align. The alignment of the pads (i.e., metallization) 103,113 may help to reduce shadowing on the bottom junction 105 (i.e., cell) during operation.

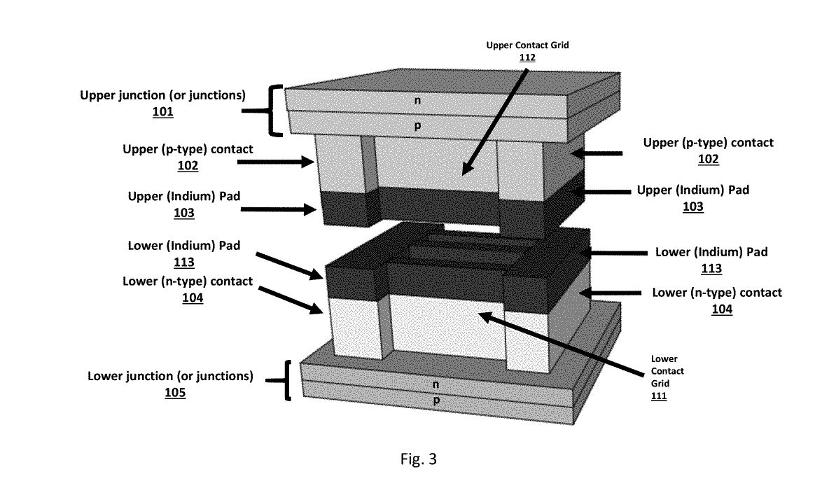

An exploded perspective view of an MJ solar cell structure with aligned pads is shown in FIG. 3. As shown, the junctions may be connected via intermetallic bonding without tunnel junctions or wafer bonding. The upper/lower junctions 101,105 have contacts 102,104 deposited on their bottom/top surfaces respectively. The material type for each contact is chosen based on the surface in which the contact is deposited. For example, the upper contact 102 is p-type because it is deposited (i.e., connected) to the p-type material of the upper junction 101, whereas the lower contact 104 is n-type because it is deposited on the n-type material of the lower junction 105. The upper/lower contacts 102, 104 are connected by an upper/lower contact grids 112, 111 respectively. The contact grid is composed of metallization grid lines.

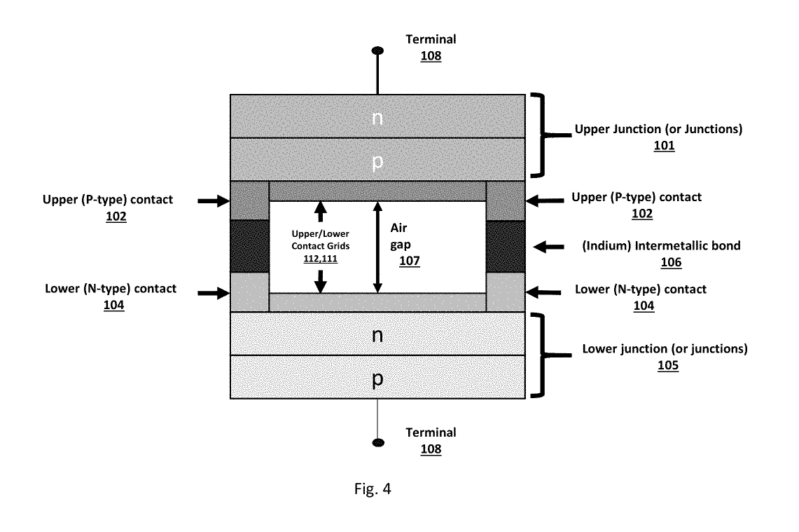

Upper/lower metallic (e.g., indium) pads 103, 113 may be connected to the upper/lower contacts respectively. In some embodiments (e.g., FIG. 3) indium pads cover both the contacts and the grid lines, while in other embodiments only the contacts may be covered by indium pads (e.g., FIG. 4). In some possible embodiments, the pads 103, 113 are a few microns of In or In-based alloy to facilitate the bonding process.

The upper/lower pads may be intermetallically bonded to connect the upper junction to the lower junction. Because the bond is made using metal pads, it is significantly easier to fabricate MJ structures since no lattice matching using epitaxial growth (e.g., no tunnel junction) is required. In addition, the resulting MJ structure has an air gap 107 between the junctions (i.e., cells) 101, 105, which allows for photon recycling and light trapping.

FIG. 4 diagrammatically illustrates of side view of the MJ solar cell shown in FIG. 3 after bonding. The air gap (i.e., light trap) 107 formed in the intermetallic bonded MJ solar cell enables back reflection and photon recycling through the p-n junction 101. Because the contacts (i.e., p-type, n-type) 102, 104 can be built on nearly any material, various cells 101, 105 may be combined. For example, the top cell 101 may be single junction cell (e.g., GaAs, CdTe, InGaP, CdT, Perovskite, etc.) or a multi-junction structure (e.g., GaAs/TJ/InGaP lattice matched to a GaAs substrate). Whereas, the bottom cell 105 may be a single junction (e.g., Si, Ge, CuInGaSe, etc.) or a multi-junction (e.g., InGaAsP/TJ/InGaAs).

As mentioned previously, one advantage of the intermetallic bonding is that a tunnel junction is not required. Tunnel junctions are typically current limited and deteriorate because of thermal annealing. The intermetallic bond 106 (e.g., as shown in FIG. 4) can be used at a high optical concentrations (e.g., several 1000×) without damage.

Intermetallic bonding is versatile. The intermetallic boding may be applied to any material combination (e.g., GaAs/Si, InGaP/Si/Ge, perovskite/Si, etc.) because the bonding is only between indium pads (e.g., the indium pads on the contacts and, in some cases, on the contact grids 111,112).

Intermetallic bonding is agnostic to junction (i.e., cell) technology. Developing cell technologies and existing (i.e., off the shelf) cell technologies may be utilized identically without the need for extra assembly steps. For example, a custom designed (i.e., optimally designed) perovskite cell may be easily bonded to a commercially available Si cell without the need for extra processes, such as the synthesis of III-V or perovskite cell on a Si cell and the modifications of the Si cell to accommodate for the junction temperature (TJ). In another example, a commercially available CdTe cell and a commercially available Si cell may be intermetallic bonded to form a MJ solar cell with a higher efficiency than each cell individually (i.e., multiple bandgaps sensitive to different wavelengths working together).

Intermetallic bonding facilitates structures (e.g., air gaps 107) that allow for photon recycling and light trapping. Photon recycling and light trapping improves solar cell efficiency. An exemplary air gap 107 is shown in FIG. 4. The air gap 107 is between the bottom surface of the top (i.e., upper) cell 101 and the top surface of the bottom (i.e., lower) cell 105. The air interface of the top cell 101 is typically designed to allow for a very narrow escape cone of photons leaving the top cell to enhance the photon recycling. In addition, the surface texture of the top surface of the bottom cell (e.g., Si cell) 105 may be configured to provide ideal coupling between the incident light and the full internal optical phase space of the bottom cell. Further, antireflection coatings and/or textured structures for the bottom and upper surfaces of the top and bottom cells respectively may be used to facilitate solar cell operation.

Both photon recycling and light trapping allow the use of an ultra-thin top cell 101, which provides a substantial material savings. The substantial material savings is not found in other approaches, which are known in the art (e.g., those which use embedded Bragg reflectors). Those approaches achieved photon recycling through the use of epoxy at the interface. As a result, access to the surfaces of the top and bottom cell resulted in a 4-terminal MJ structure. On the other hand, the intermetallic bonded MJ solar cell is a two terminal 108 device, which is more practical.

Intermetallic bonding is different from the In-bump bonding known in the art, which requires careful alignment and many fabrication steps. The intermetallic bonded MJ solar cell may use pads 103 that can be several millimeter long and several hundred microns wide. Thus, mechanical alignment can achieved with only a required accuracy of a couple of mils (i.e., 50 microns). This mechanical alignment will allow alignment of at least 50% of the pad area.

The mechanical properties of the bonded structure vary as a function of the pad area and the configuration. For embodiments used in sun applications, the pad area may be configured to reduce shadowing losses while maintaining mechanical strength of the bonded surface. In applications with high solar concentration, the area of the bonded pad may be adjusted within a range, as a particular area may be less critical.

Alloyed contact metallization may be used in the intermetallic bonded MJ solar cell structure. The bonding process may include applying an elevated temperature and pressure on the two cells. For example, the bonding process may include heating the structure to approximately 175° C. to melt the indium over layers together and then cooling the structure to form the intermetallic bond. In some cases the indium layers do not melt completely in the bonding process (i.e., due to temperature) but become tacky. When the tacky indium layers are pressed together, an intermetallic bond is formed.

The bonding process can also take place at room temperature. Here, the intermetallic bond may result from pressing the upper and lower pads together at room temperature (i.e., without applying any added heating). In other words, the bonding process includes only applying an elevated pressure on the two cells. Because the indium may not be fully melted by the elevated pressure, it is less likely to diffuse and short circuit the junction. Of course, heating above room temperature can improve bonding adhesion. Accordingly, a good bonding process may be a balance of these considerations.

The height of the air gap 107 shown in FIG. 4 may be optimized for the optimum reflection of photons at the bottom surface of the top cell 101, versus the total thickness of evaporated metal pads. In embodiments with high solar concentration, the air gap height may be reduced to improve heat dissipation without compromising the reflectivity of the bottom surface of the top cell (e.g., by evanescent coupling). For example, an air gap 107 height of few microns may be appropriate very modest temperature rise of the top cell at high values of optical concentration.

In one possible embodiment, bonding occurs at the metal pads 103. However, in another possible embodiment bonding may include the use flip-chip technology/processing. The flip-chip approach may allow the alignment between the upper and lower grids, which could be part of the bonded surfaces.

Instead of metal pads, the flip-chip bond may use metallic (e.g., indium) bumps 109 for connecting the upper 101 and lower 105 cells (i.e., the junctions). The flip-chip bond may be stronger than the bond of the metal pads shown in FIG. 3.

In some embodiments, the metallic In bumps are produced by evaporation, with diameter of about 100 microns and thickness of about 5-8 microns spaced several hundred microns apart depending on the design of the contact grid. The evaporation is followed by reflow step to form In bumps. The reflow takes place in a hydrogen environment to get rid of In oxides to facilitate the formation of bumps. The resulting bumps have a thickness and diameter, adapted for the heating and compression of the bonding process.

In other embodiments, the indium (In) bumps are formed by the deposition of In discs followed by a re-flow at high temperature (e.g., above In melting point). In this way, an In disc is transformed into an In bump with a smaller diameter and larger thickness.

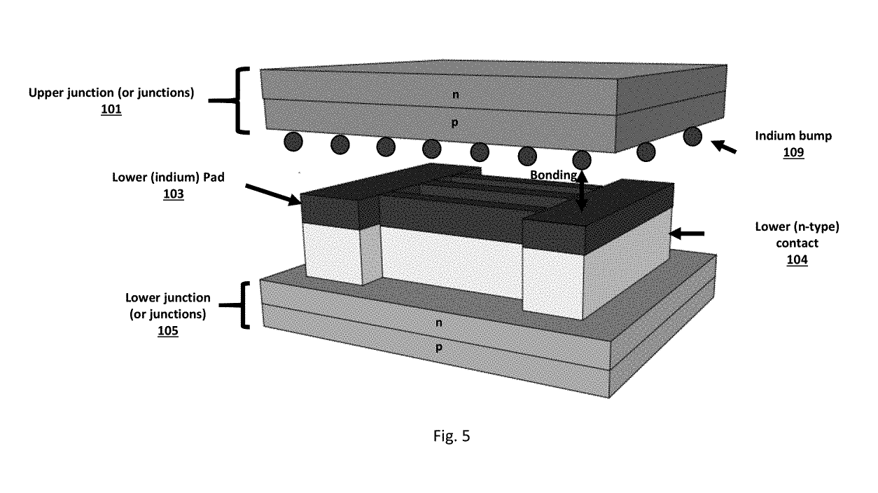

Another exemplary embodiment of a MJ solar cell bonded using indium bumps is shown in FIG. 5. As shown, (i.e., indium) bumps 109 are connected to the bottom surface of the upper cell 101. Assembly may including aligning the bumps with the n-type contact on the top surface of the bottom cell, bringing the surfaces together, heating the structure (i.e., In bumps) to melt (or make soft and/or tacky) the In bumps, and cooling the structure (i.e., the bumps) to form an intermetallic bond.

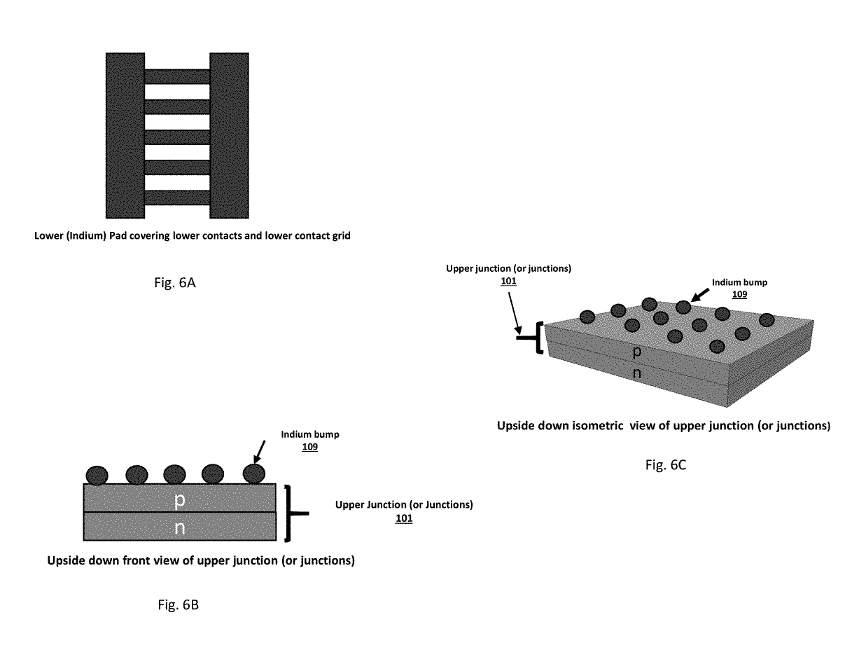

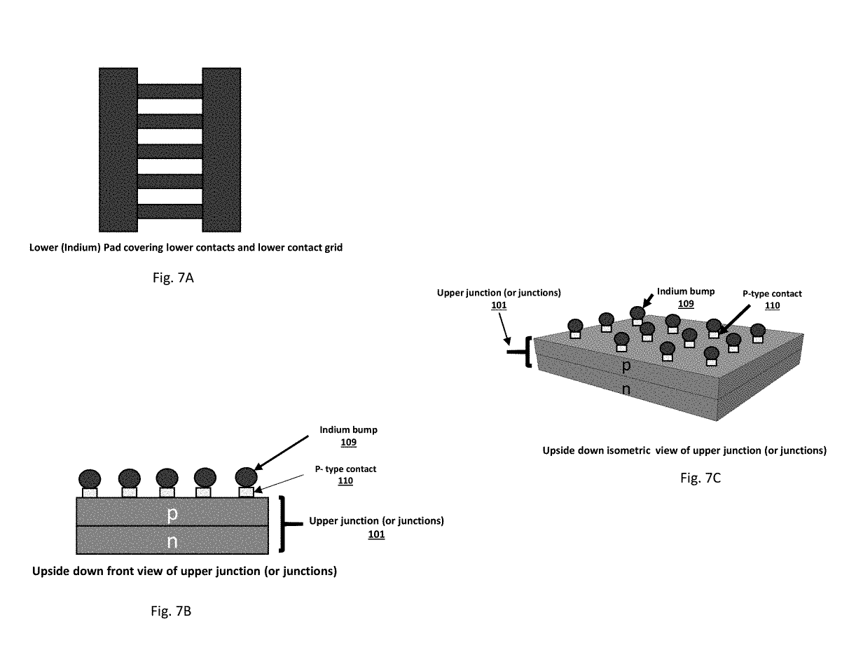

The components of the MJ solar cell shown in FIG. 5 are illustrated in FIGS. 6A-6C. FIG. 6A is a top view of a bottom cell before the indium bonding process. FIG. 6B is a side view of a top (i.e., upper) cell (shown upside down). FIG. 6C is an isometric view of the top cell (or cells). As shown, the indium bumps 109 are connected directly to the upper cell 101 (i.e., upper p-n junction). In an alternative embodiment shown in FIGS. 7A-7C, the indium bumps 109 may be connected to the cell 101 via p-type contacts 110. FIG. 7A is a top view of a bottom cell 105 before the bonding process, where the lower contact and lower contact grid is covered by a thin In layer. FIG. 7B is a side view of a top (i.e., upper) cell (shown upside down) illustrating the p-type contact positioned between the indium bump 109 and the upper cell 101. FIG. 7C is an isometric view of the top cell (or cells) 101.

For exemplary sun applications, contact grids having a 500-micron grid line spacing may be adequate. As a result, a possible MJ solar cell embodiment may include a grid comprising 100 micron square pads spaced 500 microns apart to carry out both bonding and current collection. The resulting grid creates a 4% obscuration without the need for the grid lines, and still permits mechanical alignment during assembly.

The exemplary MJ solar cell embodiments described in the present disclosure refer to “upper” and “lower” features (e.g., contacts, grids, etc.). Here, the terms “upper” and “lower” are used to describe the position of one feature with respect to another and should not be construed as limiting the MJ solar cell to a particular frame of reference. Further, the exemplary structures described could be inverted. For example, the lower junction, shown in FIG. 5, could have indium bumps, while the upper junction could have an indium pad without affecting the resulting MJ solar cell.

The methods and structures envisioned by the present disclosure include all semiconductor structures, applications, and processing techniques in which multiple junctions are used. For example, a light emitting diode (LED) comprising multiple p-n junctions, each emitting light at different wavelengths (e.g., to create a white light LED or to create an LED that emits a plurality of colored light) may be created using the structure and techniques described herein. As such, the scope of the present disclosure is not limited to multi-junction solar cells.

### Measured Results

Measurements were performed to demonstrate the validity of the disclosed intermetallic bonding approach for various materials and structures. The measurements that follow are based on structures that include intermetallic bonds formed at room temperature (i.e., room temperature bonding).

Room temperature bonding was accomplished using a bonding station having two plates: one fixed and one movable. Two cells, having dimensions of about 0.5 cm×0.5 cm were aligned as in FIG. 2 and placed between the two plates. A pressure, in the range of approximately 5-10 pounds, was applied by moving the movable plate towards the fixed plate. The pressure applied was sufficient to form an intermetallic bond with a strength suitable for the following measurements. Stronger bonds may be achieved by applying heat while applying pressure. For example, raising the indium to a temperature in the range of about 50 to 150° C. while applying pressure may provide a stronger intermetallic bond.

Mechanical adhesion was measured for materials, such as GaAs or Si. Samples of these materials were bonded according to the disclosed techniques. Each sample survived all device processing steps, such as spinning at 3000 rpm and an ultrasonic bath.

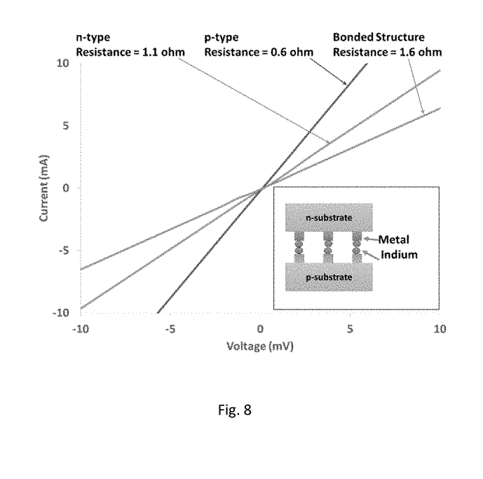

Substrates of n-type and p-type GaAs were bonded using the disclosed techniques and resistivity was measured. The results of the measurements for the bonded structure (see inset) are shown in FIG. 8. The current-voltage (I-V) plots of the FIG. 8 illustrate a low resistivity of the bonded structure. In particular, the I-V plots of the bonded n-GaAs with p-GaAs shows the In—In bonding did not substantially add resistance to the composite structure. In other words, the connection junction provided a very low resistance.

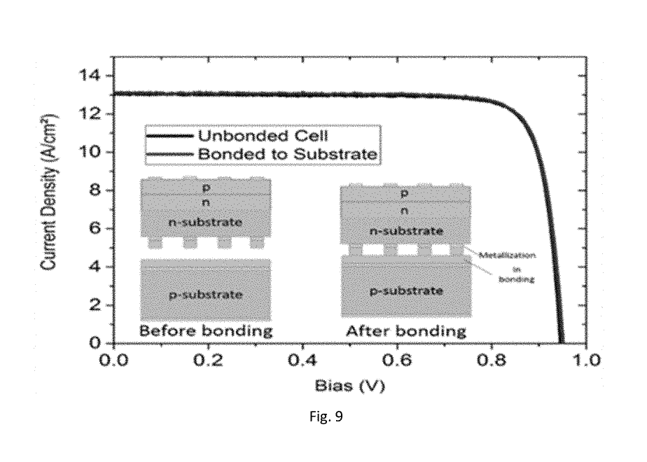

FIG. 9 graphically illustrates the effect of intermetallic bonding on a GaAs junction (see inset). As shown in FIG. 9, plots of I-V characteristics of a GaAs cell gown on an n-type substrate before and after bonding to a p-type GaAs substrate indicate minimum related changes due to the bonding, which is indicative of a good interconnect.

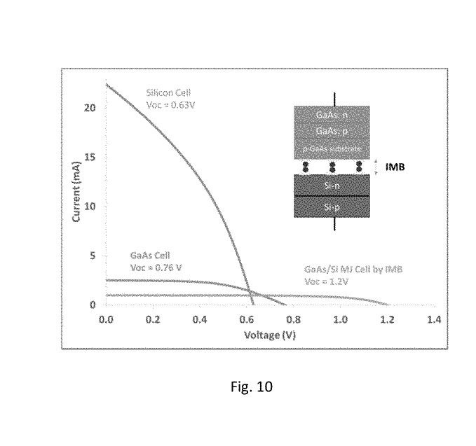

FIG. 10 graphically illustrates I-V characteristics of a single junction Si solar cell, single junction GaAs solar cell, and a tandem GaAs/Si bonded solar cell using intermetallic bonding (IMB). The GaAs/Si solar cell (see inset) was constructed from a grown (e.g., GaAs) cell and a commercially available cell (e.g., Si). The I-V plot in FIG. 10 shows a voltage addition for a multi-junction structure.

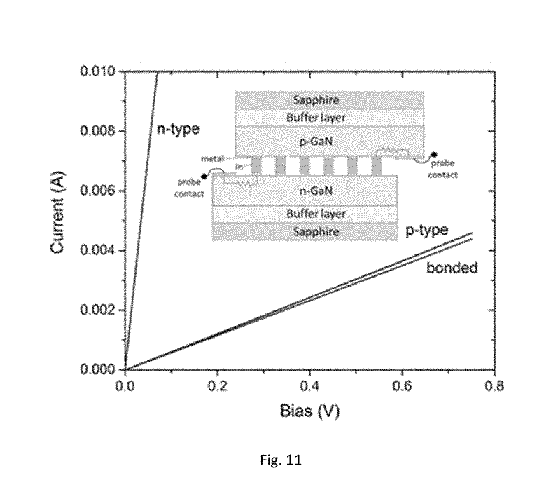

Besides bonding GaAs/GaAs, GaAs/Si, GaAs/CIGS, and GaAs/Si tandem solar cells, the intermetallic bonding technique may be applied as an interconnection between p-type GaN and n-type GaN (a substitute for the tunnel junction) as shown in FIG. 11 (see inset). As shown in the I-V plots, the bonding process did not add any resistance between the n-type and p-type layers. The main source resistance is due to the sheet resistance between the bonding pads and the contact pads. This is especially true for the p-type film with very low hole mobility.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

1. An intermetallic bonded multi-junction (MJ) solar cell, comprising:
an upper junction;
upper contacts deposited on a bottom surface of the upper junction and interconnected by an upper contact grid;
upper pads deposited on (i) the upper contacts or (ii) the upper contacts and upper contact grid;
a lower junction;
lower contacts deposited on a top surface of the lower junction and interconnected by a lower contact grid; and
lower pads deposited on (i) the lower contacts or (ii) the lower contacts and lower contact grid, wherein
the upper pads and the lower pads are connected by an intermetallic bond.

2. The intermetallic bonded MJ solar cell according to claim 1, wherein one or more of the upper junction or the lower junction are single p-n junctions or wherein one or more of the upper junction or the lower junction are multiple p-n junctions.

3. The intermetallic bonded MJ solar cell according to claim 1, wherein the upper junction is a first material combination and the lower junction is a second material combination.

4. The intermetallic bonded MJ solar cell according to claim 3, wherein the first material combination and the second material combination differ in one or more of crystalline characteristics, electrical characteristics, thermal characteristics, and optical performance characteristics.

5. The intermetallic bonded MJ solar cell according to claim 1, wherein (i) the bottom surface of the upper junction is a p-type material and the upper contact is a p-type material and (ii) the top surface of the lower junction is an n-type material and the lower contact is an n-type material.

6. The intermetallic bonded MJ solar cell according to claim 1, wherein (i) the upper pads comprise a single layer of Indium or Indium-based alloy that covers the upper contacts and upper contact grid uniformly and (ii) the lower pads comprise a single layer of Indium or Indium-based alloy that covers the lower contacts and lower contact grid uniformly.

7. The intermetallic bonded MJ solar cell according to claim 1, wherein the upper and lower pads are Indium or Indium-based alloy.

8. The intermetallic bonded MJ solar cell according to claim 7, wherein the intermetallic bond is a result of raising the temperature of the upper and lower pads to approximately melting point of Indium or Indium based alloy and pressing the upper and lower pads together or wherein the intermetallic bond is a result of pressing the upper and lower pads together at room temperature.

9. The intermetallic bonded MJ solar cell according to claim 1, wherein the upper contact, and the lower contact form an air gap.

10. The intermetallic bonded MJ solar cell according to claim 9, wherein the air gap is a light trap for photon recycling.

11. The intermetallic bonded MJ solar cell according to claim 9, wherein the upper and/or lower junction has a surface texture for coupling light.

12. The intermetallic bonded MJ solar cell according to claim 9, wherein the upper and/or lower junction has an optical antireflection coating.

13. An intermetallic bonded multi-junction (MJ) structure, comprising:
an upper junction;
a first Indium pad connected to the bottom surface of the upper junction;
a lower junction;
lower contacts deposited on a top surface of the lower junction and interconnected by a lower contact grid;
a second Indium pad covering the lower contacts and lower contact grid, wherein the first Indium pad and the second Indium pad are connected by an intermetallic bond.

14. The intermetallic bonded MJ structure according to claim 13, wherein the intermetallic bond is formed by one or more of heating, pressure, pressure at room temperature, or pressure with heating above the room temperature.

15. The intermetallic bonded MJ structure of claim 13, wherein one or more of the first Indium pad and the second Indium pad are comprised of a plurality of Indium bumps.

16. The intermetallic bonded MJ structure of claim 13, wherein the intermetallic bonded MJ structure comprises a intermetallic bonded MJ solar cell.

17. The intermetallic bonded MJ structure of claim 13, wherein the intermetallic bonded MJ structure comprises a light-emitting diode (LED) and said LED comprises a white light LED or a dual-colored light LED.

18. A method for forming an intermetallic bonded multi-junction (MJ) structure, comprising:
providing a first junction and a second junction, wherein each junction includes indium pads;
bringing the first junction's indium pads in contact with the second junction's indium pads; and
forming an intermetallic bond between the first junction's indium pads and the second junction's indium pads.

19. The method according to claim 18, wherein forming the intermetallic bond between the first junction's indium pads and the second junction's indium pads comprises one or more of:
heating the indium pads to less than the indium melting temperature and cooling the indium pads so that the intermetallic bond is formed;
applying pressure at room temperature to one or both of the first junction's indium pads and the second junction's indium pads to form the intermetallic bond; or
applying pressure with heating above the room temperature to one or both of the first junction's indium pads and the second junction's indium pads to form the intermetallic bond.

20. The method according to claim 19, wherein the first junction includes the first junction's Indium pads and a first junction's contact grid covered with Indium and wherein the second junction includes the second junction's Indium pads and a second junction's contact grid covered with Indium and wherein the first junction's Indium pads and contact grid covered with indium are brought in contact with the second junction's indium pads and contact grid covered with indium to form the intermetallic junction.

21. The method of claim 19, wherein one or both of the first junction's Indium pads and the second junction's Indium pads comprise a plurality of Indium bumps.

22. The method according to claim 21, wherein the second junction's Indium pads comprise Indium bumps and the Indium bumps are connected to the second junction via contacts situated between each Indium bump and the second junction.
